(19) United States
(12) Patent Application Publication
(10) Pub. No.: US 2025/0178149 A1
(43) Pub. Date: Jun. 5, 2025

(54) SUBSTRATE POLISHING APPARATUS

(71) Applicant: EBARA CORPORATION, Tokyo (JP)

(72) Inventors: Akihiro YAZAWA, Tokyo (JP); Kenichi KOBAYASHI, Tokyo (JP); Hirotaka OHASHI, Tokyo (JP); Sho ISHIKAWA, Tokyo (JP); Makoto KASHIWAGI, Tokyo (JP); Yasuyuki MIYASAWA, Tokyo (JP)

(21) Appl. No.: 18/840,437

(22) PCT Filed: Feb. 10, 2023
(86) PCT No.: PCT/JP2023/004509

§ 371 Date: Aug. 21, 2024

(30) Foreign Application Priority Data
Feb. 25, 2022 (JP) 2022-027736
Feb. 8, 2023 (JP) 2023-017612

(51) Int. Cl. B24B 21/00; B24B 21/08; B24B 49/10

(52) U.S. Cl. CPC B24B 21/002; B24B 21/08; B24B 49/10

(57) ABSTRACT

The present invention relates to a substrate polishing apparatus for polishing a substrate, such as a wafer, and more particularly to a substrate polishing apparatus for polishing a notch of a substrate, a bevel portion of the substrate, a device surface of the substrate, and a back surface of the substrate. The substrate polishing apparatus includes: a first polishing module; a second polishing module; and a third polishing module; wherein the first polishing module, the second polishing module, and the third polishing module are configured to polish different regions of a substrate.

### TECHNICAL FIELD

The present invention relates to a substrate polishing apparatus for polishing a substrate, such as a wafer, and more particularly to a substrate polishing apparatus for polishing a notch of a substrate, a bevel portion of the substrate, a device surface of the substrate, and a back surface of the substrate.

### BACKGROUND ART

Management of a surface condition of a substrate has recently attracted attention from the viewpoint of an increase in a yield in manufacturing of semiconductor devices. In a semiconductor device manufacturing process, films of various materials are formed on a silicon wafer. Therefore, an unnecessary film or surface roughness may be formed on a periphery of the substrate. These days it is a common practice to transport a substrate by holding only a periphery of the substrate with arms. With such a background, an unnecessary film, remaining on the periphery of the substrate, may peel off during various processes and may adhere to devices formed on the substrate, resulting in a reduced yield. Thus, in order to remove the unnecessary film from the periphery of the substrate, polishing of the periphery of the substrate is performed by a substrate polishing apparatus.

A bevel portion and a notch are generally formed in the periphery of the substrate. The bevel portion is a chamfered portion in the periphery of the substrate, which is formed so as to prevent chipping of the substrate and generating of particles. The notch is a cut formed in the periphery of the substrate to indicate a crystal orientation. The substrate polishing apparatus for polishing the periphery of the substrate described above can be categorized as a bevel polishing apparatus for polishing the bevel portion or a notch polishing apparatus for polishing the notch.

Devices, such as a memory circuit, a logic circuit, and an image sensor (e.g., a CMOS sensor) are becoming more highly integrated these days. In a process of forming such devices, foreign matter, such as fine particles or dust, may adhere to the devices. Foreign matter adhering to a device can cause a short-circuit between interconnects or can cause a circuit defect. Therefore, in order to enhance a reliability of the device, it is necessary to clean a substrate on which the device is formed to remove the foreign matter on the substrate.

Foreign matter, such as fine particles or dust, as described above may also adhere to a back surface (or a non-device surface) of the substrate. If such foreign matter adheres to the back surface of the substrate, the substrate can separate from a stage reference plane of an exposure apparatus, or a surface of the substrate can incline with respect to the stage reference plane. As a result, patterning shift or focal distance shift can occur. In order to prevent such problems, polishing of the back surface of the substrate is performed by a back-surface polishing apparatus.

A device surface of the substrate may also be slightly polished to remove sticky foreign matter adhering to the device surface of the substrate or to remove micro-scratches on the device surface of the substrate.

### CITATION LIST

### Patent Literature

Patent document 1: Japanese laid-open patent publication No. 2019-87655

### SUMMARY OF INVENTION

### Technical Problem

When polishing of the bevel portion of the substrate, polishing of the notch of the substrate, polishing of the back surface of the substrate, and polishing of the device surface of the substrate as described above are performed, four types of apparatus which are a bevel polishing apparatus, a notch polishing apparatus, a back-surface polishing apparatus, and a device-surface polishing apparatus are used. When the substrate is transported to a different type of substrate polishing apparatus, the substrate needs to be cleaned and dried each time. Therefore, improvement of the throughput of the entire process has been an issue.

Thus, the present invention provides a substrate polishing apparatus capable of shortening an overall processing time when performing a plurality of types of polishing.

### Solution to Problem

In one embodiment, there is provided a substrate polishing apparatus comprising: a first polishing module; a second polishing module; and a third polishing module; wherein the first polishing module, the second polishing module, and the third polishing module are configured to polish different regions of a substrate.

In one embodiment, the first polishing module, the second polishing module, and the third polishing module are aligned in a straight line when viewed from above the substrate polishing apparatus.

In one embodiment, the first polishing module is one of a notch polishing module configured to polish a notch of the substrate, a bevel polishing module configured to polish a bevel portion of the substrate, and a back-surface polishing module configured to polish a back surface of the substrate, the second polishing module is other one of the notch polishing module, the bevel polishing module, and the back-surface polishing module, and the third polishing module is a remaining one of the notch polishing module, the bevel polishing module, and the back-surface polishing module.

In one embodiment, the first polishing module is one of a device-surface polishing module configured to polish a device surface of the substrate, a bevel polishing module configured to polish a bevel portion of the substrate, and a back-surface polishing module configured to polish a back surface of the substrate, the second polishing module is other one of the device-surface polishing module, the bevel polishing module, and the back-surface polishing module, and the third polishing module is a remaining one of the device-surface polishing module, the bevel polishing module, and the back-surface polishing module.

In one embodiment, the substrate polishing apparatus further comprises: a housing, wherein the first polishing module, the second polishing module, and the third polishing module are arranged in the housing.

In one embodiment, the substrate polishing apparatus further comprises: a first control module configured to control an operation of the first polishing module; a second control module configured to control an operation of the second polishing module; and a third control module configured to control an operation of the third polishing module, wherein the first to third polishing modules and the first to third control modules are detachably arranged in the housing.

In one embodiment, the first to third polishing modules have the same size, and the first to third control modules have the same size.

In one embodiment, the substrate polishing apparatus further comprises: a management controller configured to control operations of the first to third polishing modules and the first to third control modules, wherein the first control module includes a first wire connector which can be electrically coupled to the management controller and the first polishing module, the second control module includes a second wire connector which can be electrically coupled to the management controller and the second polishing module, and the third control module includes a third wire connector which can be electrically coupled to the management controller and the third polishing module.

In one embodiment, the substrate polishing apparatus further comprises: a fourth polishing module arranged in the housing; a fourth control module detachably arranged in the housing, the fourth control module being configured to control an operation of the fourth polishing module; an abnormality detecting system configured to detect an abnormality that occurs in any one of the first to fourth polishing modules; and a management controller configured to control operations of the first to fourth polishing modules and the first to fourth control modules, wherein each of the first polishing module and the fourth polishing module is one of a notch polishing module configured to polish a notch of the substrate, a bevel polishing module configured to polish a bevel portion of the substrate, a back-surface polishing module configured to polish a back surface of the substrate, and a device-surface polishing module configured to polish a device surface of the substrate, and the management controller is configured to create a process flow which is performed using the fourth polishing module and without using the first polishing module when the abnormality detecting system detects an abnormality in the first polishing module.

In one embodiment, the substrate polishing apparatus further comprises: a first control module configured to control an operation of the first polishing module; a second control module configured to control an operation of the second polishing module; a third control module configured to control an operation of the third polishing module; and a management controller configured to control operations of the first to third polishing modules and the first to third control modules, wherein the first control module includes a first wire connector which can be electrically coupled to the management controller and the first polishing module, the second control module includes a second wire connector which can be electrically coupled to the management controller and the second polishing module, and the third control module includes a third wire connector which can be electrically coupled to the management controller and the third polishing module.

In one embodiment, the substrate polishing apparatus further comprises: a fourth polishing module; a fourth control module configured to control an operation of the fourth polishing module; and an abnormality detecting system configured to detect an abnormality that occurs in any one of the first to fourth polishing modules, wherein each of the first polishing module and the fourth polishing module is one of a notch polishing module configured to polish a notch of the substrate, a bevel polishing module configured to polish a bevel portion of the substrate, a back-surface polishing module configured to polish a back surface of the substrate, and a device-surface polishing module configured to polish a device surface of the substrate, and the management controller is configured to control operations of the first to fourth polishing modules and the first to fourth control modules, the management controller being configured to create a process flow which is performed using the fourth polishing module and without using the first polishing module when the abnormality detecting system detects an abnormality in the first polishing module.

### Advantageous Effects of Invention

According to the present invention, the substrate polishing apparatus includes at least three of the notch polishing module, the bevel polishing module, the back-surface polishing module, and the device-surface polishing module, so that the substrate polishing apparatus can successively perform polishing of the substrate by the at least three types of polishing modules. Therefore, it is not necessary to clean and dry the substrate every time polishing in each polishing module is terminated, and as a result, the overall processing time can be shortened.

Further, according to the present invention, the types or the arrangements of the polishing modules can be changed in the substrate polishing apparatus according to the process flow or the polishing time in each polishing module. Therefore, the single substrate polishing apparatus can perform various polishing processes to achieve an efficient process flow.

Furthermore, according to the present invention, the substrate polishing apparatus includes a plurality of polishing modules of the same type. When an abnormality is detected in one of the plurality of polishing modules by the abnormality detecting system, the process flow can be changed so as to not use the polishing module in which the abnormality has been detected. Therefore, the processing of the substrate can be continued without stopping the operations of the entire substrate polishing apparatus.

### BRIEF DESCRIPTION OF DRAWINGS

FIG. 1 is a plan view showing an embodiment of a substrate polishing apparatus;

FIG. 2 is a side view showing the substrate polishing apparatus shown in FIG. 1 as viewed from a direction indicated by an arrow A;

FIG. 3 is a schematic diagram showing an embodiment of a notch polishing module;

FIG. 4 is a plan view of the notch polishing module shown in FIG. 3;

FIG. 5 is a schematic diagram showing an embodiment of a bevel polishing module;

FIG. 6 is a schematic diagram showing an embodiment of a back-surface polishing module;

FIG. 7 is a diagram showing an example of a process flow of the substrate polishing apparatus according to the present embodiment;

FIG. 8 is a schematic diagram showing another embodiment of the substrate polishing apparatus;

FIG. 9 is a diagram showing a process flow before an abnormality is detected;

FIG. 10 is a diagram showing a process flow changed after the abnormality in a polishing module is detected;

FIG. 11 is a schematic diagram showing still another embodiment of the substrate polishing apparatus;

FIG. 12 is a schematic diagram showing an embodiment of a device-surface polishing module;

FIG. 13 is a diagram showing an example of a process flow of the substrate polishing apparatus according to the present embodiment;

FIG. 14 is a diagram showing a process flow before an abnormality in the substrate polishing apparatus shown in FIG. 11 is detected;

FIG. 15 is a diagram showing a process flow after an abnormality of a polishing module 4B in the substrate polishing apparatus shown in FIG. 11 is detected;

FIG. 16 is a plan view showing still another embodiment of the substrate polishing apparatus; and

FIG. 17 is a side view showing the substrate polishing apparatus shown in FIG. 16 as viewed from a direction indicated by an arrow B.

### DESCRIPTION OF EMBODIMENTS

Hereinafter, embodiments of the present invention will be described with reference to the drawings.

FIG. 1 is a plan view showing an embodiment of a substrate polishing apparatus. An arrow in FIG. 1 indicates a transporting direction of a substrate. The substrate polishing apparatus includes a housing 1, a load port 2, a polishing module 4A, a polishing module 4B, a polishing module 4C, a polishing module 4D, a first temporary station 6, a second temporary station 7, a third temporary station 8, a cleaning-drying section 9, a first transfer robot 11, a second transfer robot 12, a third transfer robot 13, a fourth transfer robot 14, and a fifth transfer robot 15. The polishing module 4A, the polishing module 4B, the polishing module 4C, the polishing module 4D, the first temporary station 6, the second temporary station 7, the third temporary station 8, the cleaning-drying section 9, the first transfer robot 11, the second transfer robot 12, the third transfer robot 13, the fourth transfer robot 14, and the fifth transfer robot 15 are arranged in the housing 1.

Polishing-target substrates, such as wafers, are housed in substrate cassettes 16, and the substrate cassettes 16 are placed on the load port 2. The first transfer robot 11 is arranged adjacent to the load port 2. The first transfer robot 11 is configured to remove a substrate to be polished from the substrate cassette 16 on the load port 2, and place the substrate on the first temporary station 6.

The four polishing modules 4A to 4D are arranged along a longitudinal direction of the housing 1. The four polishing modules 4A to 4D are aligned in a straight line when viewed from above the substrate polishing apparatus. The polishing module 4A is adjacent to the polishing module 4B, the polishing module 4B is adjacent to the polishing modules 4A and 4C, the polishing module 4C is adjacent to the polishing modules 4B and 4D, and the polishing module 4D is adjacent to the polishing module 4C. The polishing modules 4A to 4D include three types of polishing modules which are a notch polishing module configured to polish a notch of the substrate, a bevel polishing module configured to polish a bevel portion of the substrate, and a back-surface polishing module configured to polish a back surface of the substrate. The three types of polishing modules included in the polishing modules 4A to 4D polishes different regions of the substrate, respectively. More specifically, each of the polishing modules 4A and 4B is the notch polishing module, the polishing module 4C is the bevel polishing module, and the polishing module 4D is the back-surface polishing module.

In this embodiment, the substrate polishing apparatus includes four polishing modules 4A to 4D, while the substrate polishing apparatus is not limited to this embodiment as long as the substrate polishing apparatus includes at least three polishing modules including at least three of four types of polishing modules, which are the notch polishing module, the bevel polishing module, the back-surface polishing module, and the device-surface polishing module for polishing different regions of the substrate, respectively. For example, the substrate polishing apparatus may include six polishing modules including three types of polishing modules, which are two notch polishing modules, two bevel polishing modules, and two back-surface polishing modules.

The polishing modules 4A to 4D are detachably arranged in the housing 1. Further, the polishing modules 4A to 4D have the same size. Therefore, the arrangements of the notch polishing modules, the bevel polishing module, and the back-surface polishing module constituting the polishing modules 4A to 4D can be changed. For example, the polishing module 4A and the polishing module 4B may be bevel polishing modules, the polishing module 4C may be a back-surface polishing module, and the polishing module 4D may be a notch polishing module.

In this embodiment, the notch of the substrate is polished by at least one of the polishing modules 4A and 4B. The bevel portion of the substrate is then polished by the polishing module 4C, and the back surface of the substrate is polished by the polishing module 4D. This process flow, i.e., each of the types of polishing modules to be used and the operation order of the polishing modules, is one example, and the process flow is not limited to this embodiment.

The first temporary station 6 is a temporary station on which the substrate is temporarily placed before the substrate is polished by the polishing modules 4A to 4D. In one embodiment, the first temporary station 6 may include a notch aligner (not shown). The notch aligner is a device configured to detect a notch (cut) formed in the substrate and align the notch of the substrate to a predetermined position. The specific configuration of the notch aligner is not particularly limited as long as the notch aligner can detect the notch of the substrate and align the notch of the substrate to the predetermined position.

The second transfer robot 12 is arranged adjacent to the polishing module 4A and the polishing module 4B. The second transfer robot 12 is configured to remove the substrate from the first temporary station 6, transport the substrate to the polishing module 4A and/or the polishing module 4B, and receive the substrate from the polishing module 4A and/or the polishing module 4B. Further, the second transfer robot 12 is configured to place the substrate polished by the polishing module 4A and/or the polishing module 4B on the second temporary station 7. The second temporary station 7 is a temporary station on which the substrate is temporarily placed before the substrate is polished by the polishing module 4C.

The third transfer robot 13 is arranged adjacent to the polishing modules 4C and 4D. The third transfer robot 13 is configured to remove the substrate from the second temporary station 7, transport the substrate to the polishing modules 4C and 4D, and receive the substrate from the polishing modules 4C and 4D. Further, the third transfer robot 13 is configured to place the substrate polished by the polishing modules 4C and 4D on the third temporary station 8. The third temporary station 8 is a temporary station on which the substrate is temporarily placed before the substrate is cleaned and dried by the cleaning-drying section 9.

The substrate polished by the polishing modules 4A to 4D is cleaned and dried by the cleaning-drying section 9. The cleaning-drying section 9 includes a first cleaning module 17 and a second cleaning module 18 each configured to clean the substrate polished by the polishing modules 4A to 4D, and a drying module 19 configured to dry the cleaned substrate.

The first cleaning module 17, the second cleaning module 18, and the drying module 19 are arranged along the longitudinal direction of the housing 1. The first cleaning module 17 is configured to perform scrub cleaning with use of a roll-shaped sponge member. The second cleaning module 18 is configured to perform scrub cleaning with use of a pencil-shaped sponge member. In this embodiment, the cleaning-drying section 9 includes the first cleaning module 17 and the second cleaning module 18, while in one embodiment, the cleaning-drying section 9 may include either the first cleaning module 17 or the second cleaning module 18.

The fourth transfer robot 14 is arranged adjacent to the third temporary station 8 and arranged between the first cleaning module 17 and the second cleaning module 18. The fourth transfer robot 14 is configured to remove the substrate from the third temporary station 8, and transport the substrate to the first cleaning module 17 of the cleaning-drying section 9. Further, the fourth transfer robot 14 is configured to transport the substrate between the first cleaning module 17 and the second cleaning module 18. The fifth transfer robot 15 is arranged between the second cleaning module 18 and the drying module 19. The fifth transfer robot 15 is configured to transport the substrate between the second cleaning module 18 and the drying module 19. The substrate cleaned and dried by the cleaning-drying section 9 is returned to the substrate cassette 16 of the load port 2 by the first transfer robot 11.

The substrate polishing apparatus further includes an management controller 20 electrically coupled to the polishing modules 4A to 4D (more specifically, the notch polishing module, the bevel polishing module, and the back-surface polishing module), the cleaning-drying section 9, the first transfer robot 11, the second transfer robot 12, the third transfer robot 13, the fourth transfer robot 14, and the fifth transfer robot 15. The management controller 20 is configured to control operations of the polishing modules 4A to 4D (more specifically, the notch polishing module, the bevel polishing module, and the back-surface polishing module), the cleaning-drying section 9, the first transfer robot 11, the second transfer robot 12, the third transfer robot 13, the fourth transfer robot 14, and the fifth transfer robot 15.

The management controller 20 includes a memory 20a storing information, such as the types of the polishing modules to be used, and programs for creating a process flow that is an operation sequence of the polishing modules. The management controller 20 further includes an arithmetic device 20b configured to perform arithmetic operations according to the programs. The memory 20a includes a main memory (e.g., a random access memory) to which the arithmetic device 20b is accessible, and an auxiliary memory (e.g., a hard disk drive or a solid state drive) configured to store the programs. The arithmetic device 20b includes a CPU (central processing unit), a GPU (graphic processing module), or the like configured to perform the arithmetic operations according to instructions contained in the programs stored in the memory 20a.

The management controller 20 includes at least one computer. For example, the management controller 20 may be an edge server coupled to the substrate polishing apparatus by a communication line, or a cloud server coupled to the substrate polishing apparatus by a network, such as the Internet. The management controller 20 may be a combination of a plurality of servers. For example, the management controller 20 may be a combination of an edge server and a cloud server coupled to each other by a communication network, such as the Internet or a local area network, or a combination of a plurality of servers not coupled by a communication network. However, the specific configuration of the management controller 20 is not limited to these examples.

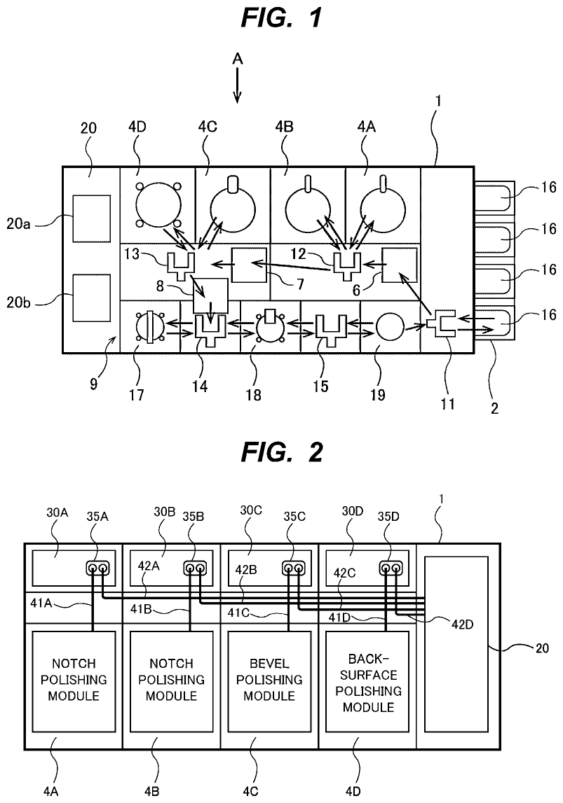

FIG. 2 is a side view of the substrate polishing apparatus shown in FIG. 1 as viewed from a direction indicated by an arrow A in FIG. 1. The substrate polishing apparatus further includes four control modules 30A to 30D configured to control the operations of the polishing modules 4A to 4D, respectively. The control module 30A is configured to control the operation of the polishing module 4A. The control module 30B is configured to control the operation of the polishing module 4B. The control module 30C is configured to control the operation of the polishing module 4C. The control module 30D is configured to control the operation of the polishing module 4D. The control modules 30A to 30D are electrically coupled to the management controller 20, and the entire control modules 30A to 30D are controlled by the management controller 20. The control modules 30A to 30D have the same size.

The control modules 30A to 30D are arranged in the housing 1, and are arranged along the longitudinal direction of the housing 1. The four control modules 30A to 30D are aligned in a straight line when viewed from above the substrate polishing apparatus. The control modules 30A to 30D are disposed above the polishing modules 4A to 4D, respectively. Specifically, the control module 30A is disposed above the polishing module 4A, the control module 30B is disposed above the polishing module 4B, the control module 30C is disposed above the polishing module 4C, and the control module 30D is disposed above the polishing module 4D.

In this embodiment, each of the control module 30A and the control module 30B is a notch-polishing control module configured to control the operations of the notch polishing module. The control module 30C is a bevel-polishing control module configured to control the operation of the bevel polishing module. The control module 30D is a back-surface-polishing control module configured to control the operation of the back-surface polishing module.

The control modules 30A to 30D are detachably arranged in the housing 1. The control modules 30A to 30D include wire connectors 35A to 35D, respectively. Specifically, the control module 30A includes the wire connector 35A, the control module 30B includes the wire connector 35B, the control module 30C includes the wire connector 35C, and the control module 30D includes the wire connector 35D.

The wire connectors 35A to 35D are coupled to polishing-module wires 41A to 41D configured to couple the control modules 30A to 30D to the polishing modules 4A to 4D, respectively. The wire connectors 35A to 35D are further coupled to body wires 42A to 42D configured to couple the control modules 30A to 30D to the management controller 20, respectively. The wire connector 35A is electrically coupled to the polishing module 4A via the polishing-module wire 41A, and is further electrically coupled to the management controller 20 via the body wire 42A. The wire connector 35B is electrically coupled to the polishing module 4B via the polishing-module wire 41B, and is further electrically coupled to the management controller 20 via the body wire 42B. The wire connector 35C is electrically coupled to the polishing module 4C via the polishing-module wire 41C, and is further electrically coupled to the management controller 20 via the body wire 42C. The wire connector 35D is electrically coupled to the polishing module 4D via the polishing-module wire 41D, and is further electrically coupled to the management controller 20 via the body wire 42D.

The polishing-module wires 41A to 41D are electrically coupled to each component of the polishing modules 4A to 4D (i.e., the notch polishing modules, the bevel polishing module, and the back-surface polishing module), which will be described later. Therefore, the polishing modules 4A to 4D can be electrically and collectively coupled to the control modules 30A to 30D by coupling the polishing-module wires 41A to 41D to the wire connectors 35A to 35D.

The body wires 42A to 42D are electrically coupled to the management controller 20. Therefore, the control modules 30A to 30D can be electrically and collectively coupled to the management controller 20 by coupling the body wires 42A to 42D to the wire connectors 35A to 35D.

With this configuration, when the arrangements of the polishing modules 4A to 4D are to be changed, the arrangements of the control modules 30A to 30D can easily be changed together with the corresponding polishing modules 4A to 4D.

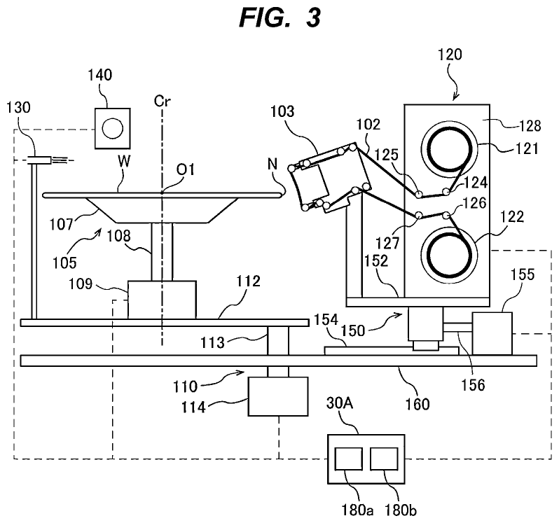

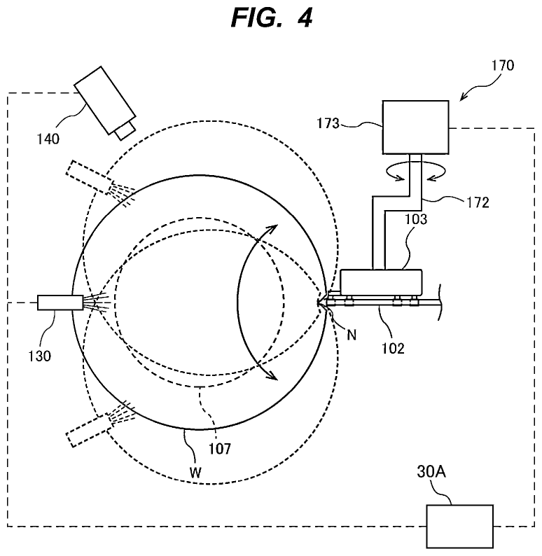

FIG. 3 is a schematic diagram showing an embodiment of the notch polishing module. FIG. 4 is a plan view of the notch polishing module shown in FIG. 3. In FIG. 4, depiction of a part of the notch polishing module is omitted. The notch polishing module is an apparatus for polishing a notch N formed in a periphery of the substrate W. As shown in FIG. 3, the notch polishing module includes a polishing head 103, a substrate holder 105, a substrate swinging structure 110, a polishing-tape feeding mechanism 120, a liquid supply nozzle 130, a notch detector 140, a polishing-head moving mechanism 150, and a tilting mechanism 170.

The substrate holder 105 is configured to hold and rotate the substrate W to be polished. The substrate holder 105 includes a holding stage 107 configured to hold the substrate W by vacuum suction, a first shaft 108 coupled to a center portion of the holding stage 107, and a holding-stage driving mechanism 109 configured to rotate and vertically move the holding stage 107. The holding-stage driving mechanism 109 is configured to rotate the holding stage 107 about its own axis Cr, and is configured to move the holding stage 107 in a vertical direction along the axis Cr.

The substrate W is placed on a substrate holding surface of the holding stage 107 by the second transfer robot 12 (see FIG. 1) such that the center O1 of the substrate W is located on the axis Cr of the holding stage 107. The substrate holder 105 can rotate the substrate W about the axis Cr of the holding stage 107 (i.e., an axis of the substrate W) and can vertically move the substrate W along the axis Cr of the holding stage 107.

The substrate swinging structure 110 is configured to rotate (i.e., swing) the substrate W in a horizontal plane by a predetermined angle clockwise and counterclockwise about the notch N of the substrate W. The substrate swinging structure 110 includes a swing arm 112 coupled to the holding-stage driving mechanism 109, a second shaft 113 coupled to the swing arm 112, and a swinging mechanism 114 configured to swing the swing arm 112.

The second shaft 113 extends through a base plate 160. The substrate holder 105 and the second shaft 113 are coupled via the swing arm 112. The swinging mechanism 114 is configured to rotate the second shaft 113 by a predetermined angle clockwise and counterclockwise. When the swinging mechanism 114 rotates the second shaft 113 clockwise and counterclockwise, the substrate holder 105 is rotated clockwise and counterclockwise together. An axis of the first shaft 108 and an axis of the second shaft 113 are offset from each other, and the notch N of the substrate W held by the holding stage 107 is located on an extension line of the axis of the second shaft 113. Therefore, as shown by the arrow in FIG. 4, the substrate W on the holding stage 107 is rotated (i.e., is swung) by the swinging mechanism 114 in the horizontal plane by the predetermined angle clockwise and counterclockwise about the notch N.

The polishing-tape feeding mechanism 120 is configured to feed a polishing tape 102 to the polishing head 103 and collect the polishing tape 102 from the polishing head 103. The polishing-tape feeding mechanism 120 includes a tape feeding reel 121 configured to feed the polishing tape 102 to the polishing head 103, and a tape take-up reel 122 configured to collect the polishing tape 102 that has been used in polishing of the substrate W. Not-shown tension motors are coupled to the tape feeding reel 121 and the tape take-up reel 122, respectively. The tape feeding reel 121 and the tape take-up reel 122 are fixed to a reel base 128 via the tension motors. The tension motors are configured to apply predetermined torque(s) to the tape feeding reel 121 and the tape take-up reel 122, so that a predetermined tension can be applied to the polishing tape 102.

The polishing-tape feeding mechanism 120 further includes a plurality of guide rollers 124, 125, 126, and 127 configured to support the polishing tape 102. The guide rollers 124, 125, 126, and 127 are fixed to the reel base 128. The polishing tape 102 is fed to the polishing head 103 such that a polishing surface of the polishing tape 102 faces the notch N of the substrate W. An advancing direction of the polishing tape 102 is guided by the guide rollers 124, 125, 126, and 127.

The liquid supply nozzle 130 is configured to supply liquid toward the notch N of the substrate W. An example of the liquid supplied to the substrate W is pure water. During polishing of the substrate W, the liquid is supplied from the liquid supply nozzle 130 toward the notch N of the substrate W. The liquid supply nozzle 130 is coupled to the swing arm 112 of the swinging mechanism 114. Therefore, the liquid supply nozzle 130 is rotated (i.e., is swung) in a horizontal plane by a predetermined angle clockwise and counterclockwise about the notch N of the substrate W together with the substrate holder 105 by the swinging mechanism 114.

The notch detector 140 is configured to detect the notch N formed in the substrate W. When the notch detector 140 detects the notch N, the holding stage 107 rotates such that the notch N faces the polishing head 103. After the substrate W is placed on the substrate holding surface of the holding stage 107 by the second transfer robot 12 (see FIG. 1), the notch detector 140 detects the notch N and aligns the notch N before polishing of the notch N.

The polishing-head moving mechanism 150 includes a guide rail 154 extending in the same direction as a line connecting the center of the substrate W on the holding stage 107 and the notch N. The guide rail 154 is fixed to the base plate 160. The polishing head 103 and the reel base 128 of the polishing-tape feeding mechanism 120 are coupled to the polishing-head moving mechanism 150 via a movable plate 152. The polishing head 103 and the entire polishing-tape feeding mechanism 120 are movable together with the movable plate 152.

The polishing-head moving mechanism 150 includes an air cylinder 155 coupled to the movable plate 152 via a coupling shaft 156. The air cylinder 155 is fixed to the base plate 160. The polishing-head moving mechanism 150 moves the polishing head 103 and the polishing-tape feeding mechanism 120 closer to and away from the notch N of the substrate W by driving the air cylinder 155 to move the movable plate 152 along the guide rail 154.

The tilting mechanism 170 is configured to tilt the polishing head 103 with respect to the substrate holding surface of the holding stage 107. More specifically, the tilting mechanism 170 includes a crank arm 172 coupled to the polishing head 103, and an arm rotating device 173 configured to rotate the crank arm 172. One end of the crank arm 172 is located at substantially the same height as the substrate holding surface of the holding stage 107, and is coupled to the arm rotating device 173. The other end of the crank arm 172 is coupled to the polishing head 103.

When the arm rotating device 173 rotates the crank arm 172, the entire polishing head 103 can be tilted about the notch N of the substrate W on the substrate holding surface of the holding stage 107. Further, the tilting mechanism 170 is configured to maintain a predetermined angle of inclination of the polishing head 103. The specific configuration of the tilting mechanism 170 is not limited to the embodiment shown in FIG. 4 as long as the polishing head 103 can be tilted with respect to the substrate holding surface of the holding stage 107 and the substrate W.

The notch polishing module is electrically coupled to the notch-polishing control module configured to control operations of each component of the notch polishing module. This notch-polishing control module corresponds to the control module 30A or 30B shown in FIG. 2, and in the following description, the notch-polishing control module is denoted by a reference symbol 30A. The substrate holder 105, the substrate swinging structure 110, the polishing-tape feeding mechanism 120, the liquid supply nozzle 130, the notch detector 140, the polishing-head moving mechanism 150, and the tilting mechanism 170 are electrically coupled to the notch-polishing control module 30A.

Operations of the substrate holder 105, the substrate swinging structure 110, the polishing-tape feeding mechanism 120, the liquid supply nozzle 130, the notch detector 140, the polishing-head moving mechanism 150, and the tilting mechanism 170 are controlled by the notch-polishing control module 30A.

The notch-polishing control module 30A includes at least one computer. The notch-polishing control module 30A includes a memory 180a storing programs therein, and an arithmetic device 180b configured to perform arithmetic operations according to the programs. The memory 180a includes a main memory (e.g., a random access memory) to which the arithmetic device 180b is accessible, and an auxiliary memory (e.g., a hard disk drive or a solid state drive) configured to store the programs. The arithmetic device 180b includes a CPU (central processing unit) or a GPU (graphic processing module), or the like configured to perform the arithmetic operations according to instructions contained in the programs stored in the memory 180a. However, the specific configuration of the notch-polishing control module 30A is not limited to these examples.

Polishing of the notch N of the substrate W is performed as follows. After the substrate W is transported to the notch polishing module, the holding stage 107 is raised, and the substrate W is placed on the substrate holding surface of the holding stage 107 and is held by vacuum suction. In this state, the notch detector 140 detects a position of the notch N of the substrate W, and the substrate holder 105 lowers the substrate W to a polishing position while rotating the holding stage 107 such that the notch N faces the polishing head 103. Further, the liquid supply nozzle 130 starts to supply the liquid to the substrate W.

Next, the polishing-head moving mechanism 150 moves the polishing head 103 closer to the notch N of the substrate W, so that the polishing head 103 bring the polishing surface of the polishing tape 102 into sliding contact with the notch N to polish the notch N. During polishing of the notch N, the substrate swinging structure 110 swings the substrate W about the notch N, and the tilting mechanism 170 tilts the polishing head 103 about the notch N.

After the substrate W is polished according to a predetermined polishing recipe, the notch-polishing control module 30A instructs the notch polishing module to terminate polishing of the substrate W. Specifically, the notch-polishing control module 30A causes the substrate swinging structure 110 and the tilting mechanism 170 to stop the operations of the substrate swinging structure 110 and the tilting mechanism 170, and causes the polishing-head moving mechanism 150 to move the polishing head 103 away from the substrate W. The notch-polishing control module 30A then causes the substrate holder 105, the polishing-tape feeding mechanism 120, and the liquid supply nozzle 130 to stop the operations of them to terminate polishing of the substrate W.

The specific configuration of the notch polishing module is not limited to the above-described embodiment as long as the notch polishing module can polish the notch N of the substrate W.

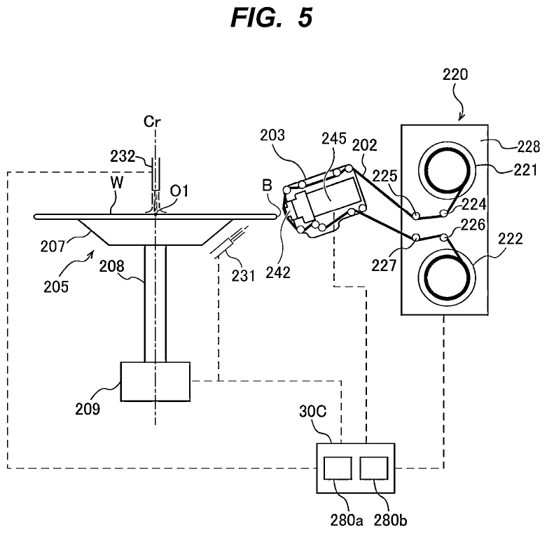

FIG. 5 is a schematic diagram showing an embodiment of the bevel polishing module. The bevel polishing module is an apparatus for polishing the periphery including the bevel portion B of the substrate W. As shown in FIG. 5, the bevel polishing module includes a polishing head 203, a substrate holder 205, a polishing-tape feeding mechanism 220, a lower supply nozzle 231, an upper supply nozzle 232, and a tilting mechanism (not shown).

The substrate holder 205 is configured to hold and rotate the substrate W. The substrate holder 205 includes a holding stage 207, a shaft 208, and a holding-stage driving mechanism 209. Configurations of the holding stage 207, the shaft 208, and the holding-stage driving mechanism 209 are the same as the configurations of the holding stage 107, the first shaft 108, and the holding-stage driving mechanism 109 of the notch polishing module described with reference to FIG. 3, and therefore duplicated descriptions will be omitted.

The polishing-tape feeding mechanism 220 is configured to feed a polishing tape 202 to the polishing head 203 and collect the polishing tape 202 from the polishing head 203. The polishing-tape feeding mechanism 220 includes a tape feeding reel 221, a tape take-up reel 222, and a plurality of guide rollers 224, 225, 226, and 227. The tape feeding reel 221, the tape take-up reel 222, and the plurality of guide rollers 224, 225, 226, and 227 are fixed to a reel base 228. The polishing tape 202 is fed to the polishing head 203 such that a polishing surface of the polishing tape 202 faces the bevel portion B of the substrate W.

Configurations of the tape feeding reel 221, the tape take-up reel 222, and the plurality of guide rollers 224, 225, 226, and 227 are the same as the configurations of the tape feeding reel 121, the tape take-up reel 122, and the plurality of guide rollers 124, 125, 126, and 127 of the notch polishing module described with reference to FIG. 3, and duplicated descriptions will be omitted.

The lower supply nozzle 231 is configured to supply liquid onto a lower surface of the substrate W. The upper supply nozzle 232 is configured to supply liquid onto an upper surface of the substrate W. An example of the liquid supplied to the substrate W is pure water. During polishing of the substrate W, the liquid is supplied from the lower supply nozzle 231 onto the lower surface of the substrate W, and the liquid is supplied from the upper supply nozzle 232 onto the upper surface of the substrate W.

The polishing head 203 includes a pressing member 242 configured to press the polishing surface of the polishing tape 202 against the bevel portion B of the substrate W, and an air cylinder (i.e., an actuator) 245 configured to move the pressing member 242 toward the bevel portion B of the substrate W. A pressing force on the polishing tape 202 against the substrate W is regulated by controlling an air pressure supplied to the air cylinder 245. The pressing member 242 is arranged at a back side of the polishing tape 202 (at a back side opposite to the polishing surface having abrasive grains).

The tilting mechanism (not shown) has the same configuration as that of the tilting mechanism 170 of the notch polishing module described with reference to FIG. 4, and duplicated descriptions will be omitted. The tilting mechanism of the bevel polishing module is configured to tilt the polishing head 203 with respect to the substrate holding surface of the holding stage 207.

The bevel polishing module is electrically coupled to the bevel-polishing control module configured to control operations of each component of the bevel polishing module. This bevel-polishing control module corresponds to the control module 30C shown in FIG. 2, and in the following description, the bevel-polishing control module is denoted by a reference symbol 30C. The substrate holder 205, the polishing-tape feeding mechanism 220, the lower supply nozzle 231, the upper supply nozzle 232, the air cylinder 245, and the tilting mechanism are electrically coupled to the bevel-polishing control module 30C. Operations of the substrate holder 205, the polishing-tape feeding mechanism 220, the lower supply nozzle 231, the upper supply nozzle 232, the air cylinder 245, and the tilting mechanism are controlled by the bevel-polishing control module 30C. The bevel-polishing control module 30C includes a memory 280a and an arithmetic device 280b. The memory 280a and the arithmetic device 280b have the same basic configuration as the memory 180a and the arithmetic device 180b of the notch-polishing control module 30A described above, and duplicated descriptions will be omitted.

Polishing of the bevel portion B of the substrate W is performed as follows. After the substrate W is transported to the bevel polishing module, the holding stage 207 is raised, and the substrate W is placed on the substrate holding surface of the holding stage 207 and is held by vacuum suction. The substrate holder 205 lowers the substrate W to a polishing position and rotates the holding stage 207. Further, the lower supply nozzle 231 and the upper supply nozzle 232 start to supply the liquid to the substrate W.

Next, the air cylinder 245 is driven to press the pressing member 242 of the polishing head 203 against the bevel portion B of the substrate W, so that the bevel portion B of the substrate W is polished. During polishing of the bevel portion B, the tilting mechanism tilts the polishing head 203 with respect to the substrate holding surface of the holding stage 207.

After the substrate W is polished according to a predetermined polishing recipe, the bevel-polishing control module 30C instructs the bevel polishing module to terminate polishing of the substrate W. Specifically, the bevel-polishing control module 30C causes the tilting mechanism to stop the operations of the tilting mechanism, and causes the air cylinder 245 of the polishing head 203 to stop driving and to move the pressing member 242 away from the substrate W. The bevel-polishing control module 30C then causes the substrate holder 205, the polishing-tape feeding mechanism 220, the lower supply nozzle 231, and the upper supply nozzle 232 to stop the operations of the substrate holder 205, the polishing-tape feeding mechanism 220, the lower supply nozzle 231, and the upper supply nozzle 232 to terminate polishing of the substrate W.

The specific configuration of the bevel polishing module is not limited to the above-described embodiment as long as the bevel polishing module can polish the bevel portion B of the substrate W.

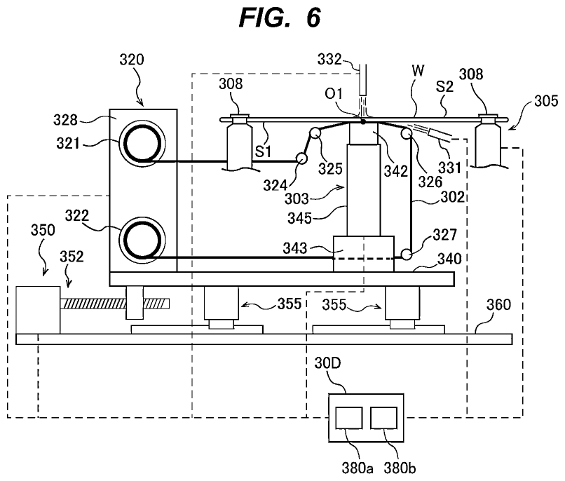

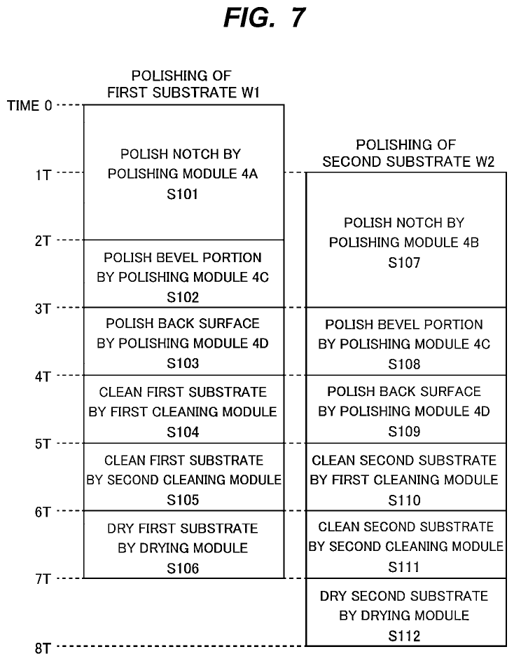

FIG. 6 is a schematic diagram showing an embodiment of the back-surface polishing module. The back-surface polishing module is an apparatus for polishing the back surface of the substrate W. As shown in FIG. 6, the back-surface polishing module includes a polishing head 303, a substrate holder 305, a polishing-tape feeding mechanism 320, a rinsing-liquid supply nozzle 331, a protective-liquid supply nozzle 332, and a polishing-head moving mechanism 350.

The substrate holder 305 includes a plurality of rollers 308 which can contact the periphery of the substrate W, and a roller rotating mechanism (not shown) configured to rotate the plurality of rollers 308 about their respective own axes. The polishing head 303 is arranged below the substrate W held by the substrate holder 305. In FIG. 6, depiction of a part of the substrate holder 305 is omitted. The substrate holder 305 of this embodiment includes four rollers 308 (two of which are not shown).

In this embodiment, a first surface S1 of the substrate W is a back surface of the substrate W on which no device is formed or device is not to be formed, i.e., a non-device surface. A second surface S2 of the substrate W, which is opposite the first surface S1, is a surface on which devices are formed or devices are to be formed, i.e., a device surface. In this embodiment, the substrate W is horizontally held by the substrate holder 305 with the first surface S1 facing downward.

The roller rotating mechanism is configured to rotate the four rollers 308 in the same direction at the same speed. During polishing of the first surface S1 of the substrate W, the periphery of the substrate W is held by the rollers 308. The substrate W is held horizontally, and is rotated about its own axis by the rotations of the rollers 308. During polishing of the first surface S1 of the substrate W, the four rollers 308 rotate about their respective own axes, while positions of the rollers 308 themselves remain stationary.

The polishing-tape feeding mechanism 320 is configured to feed a polishing tape 302 to the polishing head 303 and collect the polishing tape 302 from the polishing head 303. The polishing-tape feeding mechanism 320 includes a tape feeding reel 321 configured to feed the polishing tape 302 to the polishing head 303, and a tape take-up reel 322 configured to collect the polishing tape 302 that has been used in polishing of the substrate W. Not-shown tension motors are coupled to the tape feeding reel 321 and the tape take-up reel 322, respectively. The tape feeding reel 321 and the tape take-up reel 322 are fixed to a reel base 328 via the tension motors, and the reel base 328 is fixed to a movable plate 340. The tension motors are configured to apply predetermined torque(s) to the tape feeding reel 321 and the tape take-up reel 322, so that a predetermined tension can be applied to the polishing tape 302.

The polishing-tape feeding mechanism 320 further includes a plurality of guide rollers 324, 325, 326, and 327 configured to support the polishing tape 302. The polishing tape 302 is fed to the polishing head 303 such that a polishing surface of the polishing tape 302 faces the first surface S1 of the substrate W. The guide rollers 324, 325, 326, and 327 are fixed to a not-shown holding member, and this holding member is fixed to the movable plate 340. An advancing direction of the polishing tape 302 is guided by the guide rollers 324, 325, 326, and 327 such that the polishing tape 302 surrounds the polishing head 303. More specifically, the guide rollers 325 and 326 are arranged at an upper portion of the polishing head 303 to guide the polishing tape 302 such that the polishing tape 302 advances in a direction parallel to the first surface S1 of the substrate W.

The rinsing-liquid supply nozzle 331 is disposed below the substrate W held by the substrate holder 305, and is configured to supply a rinsing liquid toward a processing point of the first surface S1 of the substrate W. Examples of the rinsing liquid supplied to the first surface S1 of the substrate W include, e.g., pure water and an alkaline chemical liquid. The protective-liquid supply nozzle 332 is disposed above the substrate W held by the substrate holder 305, and is configured to supply a protective liquid onto the second surface S2 of the substrate W. An example of the protective liquid supplied to the second surface S2 of the substrate W includes pure water.

The polishing-head moving mechanism 350 is configured to move the polishing head 303 between the center O1 of the first surface S1 of the substrate W and an outermost portion of the first surface S1. The polishing-head moving mechanism 350 includes a plurality of linear guides 355 at a lower surface of the movable plate 340, and the movable plate 340 is supported by the plurality of linear guides 355. The plurality of linear guides 355 are arranged on a base plate 360. The linear guides 355 restrict movement of the movable plate 340 to linear movement in a radial direction of the substrate W.

The polishing head 303, the reel base 328 of the polishing-tape feeding mechanism 320, and the holding member to which the guide rollers 324, 325, 326, and 327 are fixed are coupled to the polishing-head moving mechanism 350 via the movable plate 340. The polishing head 303 and the entire polishing-tape feeding mechanism 320 are movable together with the movable plate 340.

The polishing-head moving mechanism 350 includes a ball screw mechanism 352 coupled to the movable plate 340. The ball screw mechanism 352 is fixed to the base plate 360. The polishing-head moving mechanism 350 moves the polishing head 303 and the polishing-tape feeding mechanism 320 in the radial direction of the substrate W relative to the substrate holder 305 by driving the ball screw mechanism 352. During polishing of the substrate W, the polishing-head moving mechanism 350 moves the polishing head 303 between the center O1 of the first surface S1 of the substrate W and the outermost portion of the first surface S1.

The polishing head 303 is supported by a support member 343, which is fixed to the movable plate 340. Therefore, the entire polishing head 303 is movable together with the movable plate 340. The support member 343 has a not-shown through-hole, and the polishing tape 302 extends through the through-hole. The polishing head 303 includes a pressing member 342 configured to press the polishing surface of the polishing tape 302 against the first surface S1 of the substrate W, and an air cylinder (i.e., an actuator) 345 configured to move the pressing member 342 toward the first surface S1 of the substrate W. A pressing force on the polishing tape 302 against the substrate W is regulated by controlling an air pressure supplied to the air cylinder 345. The pressing member 342 is arranged at a back side of the polishing tape 302 (at a back side opposite to the polishing surface having abrasive grains).

The back-surface polishing module is electrically coupled to the back-surface-polishing control module configured to control operations of each component of the back-surface polishing module. This back-surface-polishing control module corresponds to the control module 30D shown in FIG. 2, and in the following description, the back-surface-polishing control module is denoted by a reference symbol 30D. The substrate holder 305, the polishing-tape feeding mechanism 320, the rinsing-liquid supply nozzle 331, the protective-liquid supply nozzle 332, the polishing-head moving mechanism 350, and the air cylinder 345 of the polishing head 303 are electrically coupled to the back-surface-polishing control module 30D. Operations of the substrate holder 305, the polishing-tape feeding mechanism 320, the rinsing-liquid supply nozzle 331, the protective-liquid supply nozzle 332, the polishing-head moving mechanism 350, and the air cylinder 345 of the polishing head 303 are controlled by the back-surface-polishing control module 30D. The back-surface-polishing control module 30D includes a memory 380a and an arithmetic device 380b. The memory 380a and the arithmetic device 380b have the same basic configuration as the memory 180a and the arithmetic device 180b of the notch-polishing control module 30A described above, and duplicated descriptions will be omitted.

Polishing of the first surface S1 of the substrate W is performed as follows. After the substrate W is transported to the back-surface polishing module by the third transfer robot 13 (see FIG. 1), the substrate holder 305 holds the substrate W by the rollers 308 with the first surface S1 facing downward, and rotates the substrate W about the axis of the substrate W. Further, the rinsing-liquid supply nozzle 331 starts to supply the rinsing liquid onto the first surface S1 of the substrate W, and the protective-liquid supply nozzle 332 starts to supply the protective liquid onto the second surface S2 of the substrate W.

Next, the polishing-head moving mechanism 350 moves the polishing head 303 to a position below the center O1 of the first surface S1 of the substrate W. The air cylinder 345 is driven to press the pressing member 342 of the polishing head 303 against the first surface S1 of the substrate W, while the polishing-head moving mechanism 350 moves the polishing head 303 and the polishing-tape feeding mechanism 320 in the radially outward direction of the substrate W, so that the first surface S1 of the substrate W is polished.

When the polishing head 303 reaches the outermost portion of the first surface S1 of the substrate W, the back-surface-polishing control module 30D instructs the back-surface polishing module to terminate polishing of the substrate W. Specifically, the back-surface-polishing control module 30D causes the polishing-head moving mechanism 350 to stop the operations of the polishing-head moving mechanism 350. The back-surface-polishing control module 30D causes the air cylinder 345 to stop driving and to move the polishing head 303 to lower the pressing member 342, so that the polishing tape 302 is moved away from the first surface S1 of the substrate W. The back-surface-polishing control module 30D then causes the substrate holder 305, the polishing-tape feeding mechanism 320, the rinsing-liquid supply nozzle 331, and the protective-liquid supply nozzle 332 to stop the operations of the substrate holder 305, the polishing-tape feeding mechanism 320, the rinsing-liquid supply nozzle 331, and the protective-liquid supply nozzle 332 to terminate polishing of the substrate W. In one embodiment, the polishing-head moving mechanism 350 may reciprocate the polishing head 303 between the outermost portion and the center O1 of the first surface S1 of the substrate W.

The specific configuration of the back-surface polishing module is not limited to the above-described embodiment as long as the back-surface polishing module can polish the back surface (i.e., the first surface S1) of the substrate W.

FIG. 7 is a diagram showing an example of a process flow of the substrate polishing apparatus according to the present embodiment. In this embodiment, the notch N of the substrate W is polished by the polishing module 4A or the polishing module 4B which is the notch polishing module, the bevel portion B of the substrate W is polished by the polishing module 4C which is the bevel polishing module, and the back surface (i.e., the first surface S1) of the substrate W is polished by the polishing module 4D which is the back-surface polishing module. The polished substrate W is cleaned by the first cleaning module 17, is further cleaned by the second cleaning module 18, and is then dried by the drying module 19.

When polishing time in each polishing module is expressed in time unit T, polishing time for the notch N in the notch polishing module is 2T (twice the time unit T), polishing time for the bevel portion B in the bevel polishing module is 1T, and polishing time for the back surface in the back-surface polishing module is 1T. In addition, cleaning time in the first cleaning module 17 and the second cleaning module 18, and drying time in the drying module 19 are each 1T.

FIG. 7 shows a process flow for a first substrate W1 to be processed first and a process flow for a second substrate W2 to be processed next. Time represents elapsed time from the start of polishing of the first substrate W1.

In step S101, from time 0 to time 2T, a notch N of the first substrate W1 is polished by the polishing module 4A (i.e., the notch polishing module).

In step S102, from the time 2T to time 3T, a bevel portion B of the first substrate W1 is polished by the polishing module 4C (i.e., the bevel polishing module).

In step S103, from the time 3T to time 4T, a back surface (i.e., a first surface S1) of the first substrate W1 is polished by the polishing module 4D (i.e., the back-surface polishing module).

In step S104, from the time 4T to time 5T, the polished first substrate W1 is cleaned by the first cleaning module 17.

In step S105, from the time 5T to time 6T, the first substrate W1 that has been cleaned by the first cleaning module 17 is cleaned by the second cleaning module 18.

In step S106, from the time 6T to time 7T, the first substrate W1 that has been cleaned by the second cleaning module 18 is dried by the drying module 19.

In step S107, from time 1T to the time 3T, a notch N of the second substrate W2 is polished by the polishing module 4B (i.e., the notch polishing module).

In step S108, from the time 3T to the time 4T, a bevel portion B of the second substrate W2 is polished by the polishing module 4C (i.e., the bevel polishing module).

In step S109, from the time 4T to the time 5T, a back surface (i.e., a first surface S1) of the second substrate W2 is polished by the polishing module 4D (i.e., the back-surface polishing module).

In step S110, from the time 5T to the time 6T, the polished second substrate W2 is cleaned by the first cleaning module 17.

In step S111, from the time 6T to the time 7T, the second substrate W2 that has been cleaned by the first cleaning module 17 is cleaned by the second cleaning module 18.

In step S112, from the time 7T to time 8T, the second substrate W2 that has been cleaned by the second cleaning module 18 is dried by the drying module 19.

According to this embodiment, since the substrate polishing apparatus includes the notch polishing module, the bevel polishing module, and the back-surface polishing module in the same housing 1, the substrate polishing apparatus can successively perform polishing of the substrate by the different types of polishing modules. Therefore, it is not necessary to clean and dry the substrate W every time polishing in each polishing module is terminated, and as a result, the overall processing time can be shortened.

The substrate polishing apparatus includes the polishing module 4A and the polishing module 4B, which are notch polishing modules that require a longer polishing time than those of other processes. Therefore, the notch N of the first substrate W1 and the notch N of the second substrate W2 can be polished in parallel by the polishing module 4A and the polishing module 4B. Thus, in the bevel polishing module that performs the next process, the second substrate W2 can be polished immediately after the first substrate W1 is polished without any idle time. As a result, the overall processing time can be shortened when the plurality of substrates are processed.

The above-described process flow is an example. In one embodiment, the process flow may include polishing of the bevel portion B by the polishing module 4C which is the bevel polishing module, followed by polishing of the back surface (i.e., the first surface S1) by the polishing module 4D which is the back-surface polishing module, and then polishing of the notch N of the substrate W by the polishing module 4A or the polishing module 4B which is the notch polishing module.

The types or the arrangements of the polishing modules 4A to 4D can be changed in the substrate polishing apparatus according to the process flow or the polishing time in each polishing module. Therefore, the single substrate polishing apparatus can perform various polishing processes to achieve an efficient process flow. In one embodiment, the substrate polishing apparatus may include two first cleaning modules 17, two second cleaning modules 18, and two drying modules 19. For example, the substrate polishing apparatus may clean and dry a plurality of substrates polished by the polishing modules 4A to 4D in parallel by the two first cleaning modules 17, the two second cleaning modules 18, and the two drying modules 19.

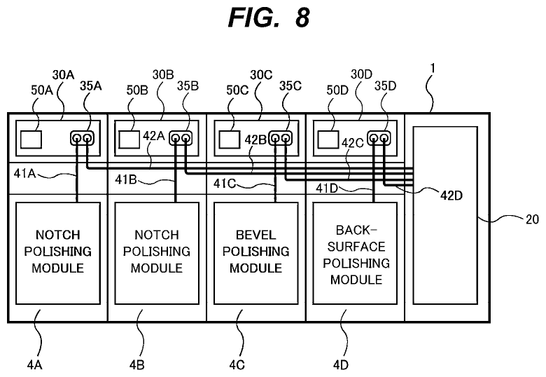

FIG. 8 is a schematic diagram showing another embodiment of the substrate polishing apparatus. Details of this embodiment, which will not be particularly described, are the same as those of the embodiment described with reference to FIGS. 1 to 7, and duplicated descriptions will be omitted. The control modules 30A to 30D of the substrate polishing apparatus shown in FIG. 8 include abnormality detecting systems 50A to 50D configured to detect an abnormality that may occur in the corresponding polishing modules 4A to 4D.

These abnormality detecting systems 50A to 50D are configured to detect an abnormality based on various signals obtained from the polishing modules 4A to 4D. Such abnormality detecting systems 50A to 50D to be used may be abnormality detecting systems including known abnormality detectors. The abnormality detecting systems 50A to 50D of this embodiment are provided for the polishing modules 4A to 4D, respectively, while in one embodiment, a single abnormality detecting system may be provided in the management controller 20 and may be configured to detect an abnormality in the polishing modules 4A to 4D.

The abnormality detecting system 50A is configured to detect an abnormality that may occur in the polishing module 4A whose operations are controlled by the control module 30A. The abnormality detecting system 50B is configured to detect an abnormality that may occur in the polishing module 4B whose operations are controlled by the control module 30B. The abnormality detecting system 50C is configured to detect an abnormality that may occur in the polishing module 4C whose operations are controlled by the control module 30C. The abnormality detecting system 50D is configured to detect an abnormality that may occur in the polishing module 4D whose operations are controlled by the control module 30D.

When an abnormality in any one of the polishing modules 4A to 4D is detected by corresponding one of the abnormality detecting systems 50A to 50D, corresponding one of the control modules 30A to 30D transmits an abnormality detection signal to the management controller 20. When the abnormality has been detected in one of polishing modules of the same type, the management controller 20 is configured to create a process flow which is performed without using the polishing module in which the abnormality has been detected.

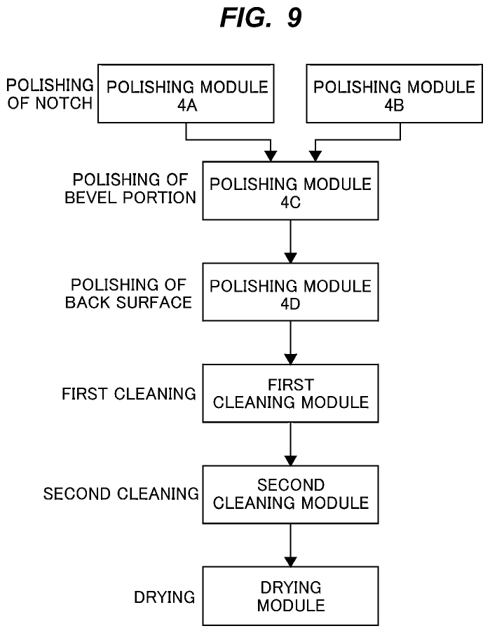

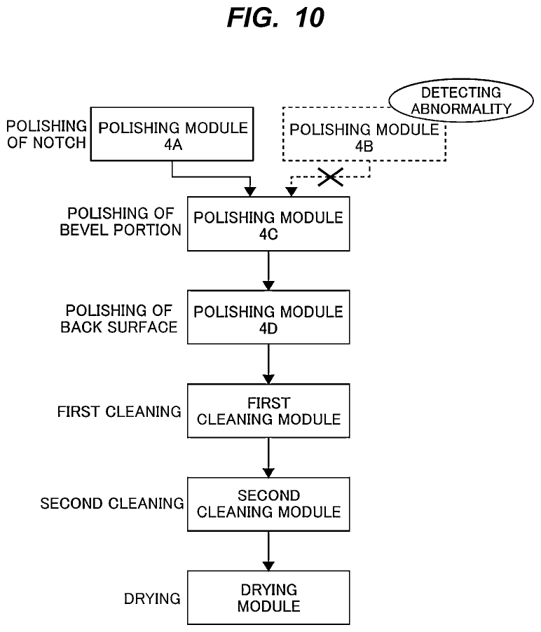

FIG. 9 is a diagram showing a process flow before an abnormality is detected. As in the embodiment described with reference to FIG. 7, polishing of the notches N of the plurality of substrates is performed in parallel by the two notch polishing modules, which are the polishing module 4A and the polishing module 4B. FIG. 10 is a diagram showing a process flow changed after the abnormality in the polishing module 4B is detected. When the abnormality in the polishing module 4B is detected by the abnormality detecting system 50B, the control module 30B transmits an abnormality detection signal to the management controller 20. The management controller 20 creates a process flow which is performed without using the polishing module 4B based on the abnormality detection signal, and changes a process flow from the process flow shown in FIG. 9 which is performed using both the polishing modules 4A and 4B to the process flow shown in FIG. 10 which is performed using the polishing module 4A and is performed without using the polishing module 4B.

In this present embodiment, the polishing module 4B in which the abnormality has been detected is one of the plurality of notch polishing modules. Therefore, when the abnormality has occurred in the polishing module 4B, the substrate polishing apparatus can continue the processing of the substrate without stopping the operations of the entire substrate polishing apparatus by changing the process flow so as to polish the notch N using only the polishing module 4A.

The substrate polishing apparatus of this embodiment includes the two notch polishing modules, while in one embodiment, the substrate polishing apparatus may include three or more notch polishing modules. When the abnormality detecting system detects an abnormality in at least one of the three or more notch polishing modules, the management controller 20 may change a process flow so as to not use the at least one notch polishing module in which the abnormality has been detected. In one embodiment, the substrate polishing apparatus may include a plurality of bevel polishing modules or a plurality of back-surface polishing modules. When the abnormality detecting system detects an abnormality in a bevel polishing module of the plurality of bevel polishing modules or a back-surface polishing module of the plurality of back-surface polishing modules, the management controller 20 may change a process flow so as to not use the bevel polishing module or the back-surface polishing module in which the abnormality has been detected.

The above-described substrate polishing apparatus includes three types of polishing modules which are the notch polishing module, the bevel polishing module, and the back-surface polishing module, while the configuration of the substrate polishing apparatus is not limited to these types of polishing modules. For example, the polishing module may be a polishing module that uses a whetstone instead of the polishing tape as a polishing tool, or a polishing module (e.g., a CMP module) that uses a polishing pad (e.g., nonwoven fabric) as the polishing tool in the presence of a polishing liquid (e.g., slurry).

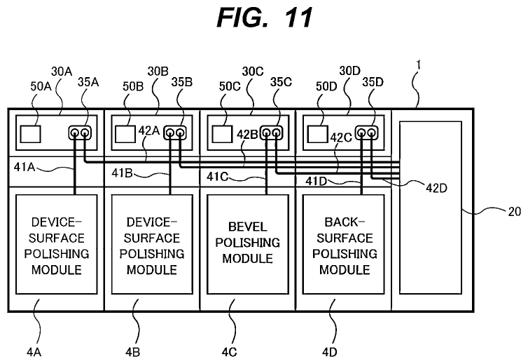

FIG. 11 is a schematic diagram showing still another embodiment of the substrate polishing apparatus. Configurations and operations of this embodiment, which will not be particularly described, are the same as those of the above-described embodiments, and duplicated descriptions will be omitted. In this embodiment, the polishing modules 4A and 4B are device-surface polishing modules configured to polish the device surface of the substrate, instead of the notch polishing modules. In this embodiment, each of the control modules 30A and 30B is a device-surface-polishing control module configured to control operations of the device-surface polishing module.

The polishing modules 4A to 4D are detachably arranged in the housing 1. Further, the polishing modules 4A to 4D have the same size. Therefore, the arrangements of the device-surface polishing modules, the bevel polishing module, and the back-surface polishing module constituting the polishing modules 4A to 4D can be changed. For example, each of the polishing module 4A and the polishing module 4B may be the bevel polishing module, the polishing module 4C may be the back-surface polishing module, and the polishing module 4D may be the device-surface polishing module.

In this embodiment, the device surface of the substrate is polished by at least one of the polishing modules 4A and 4B. The bevel portion of the substrate is then polished by the polishing module 4C, and the back surface of the substrate is polished by the polishing module 4D. This process flow, i.e., each of the types of polishing modules to be used and the operation order of the polishing modules, is one example, and the process flow is not limited to this embodiment.

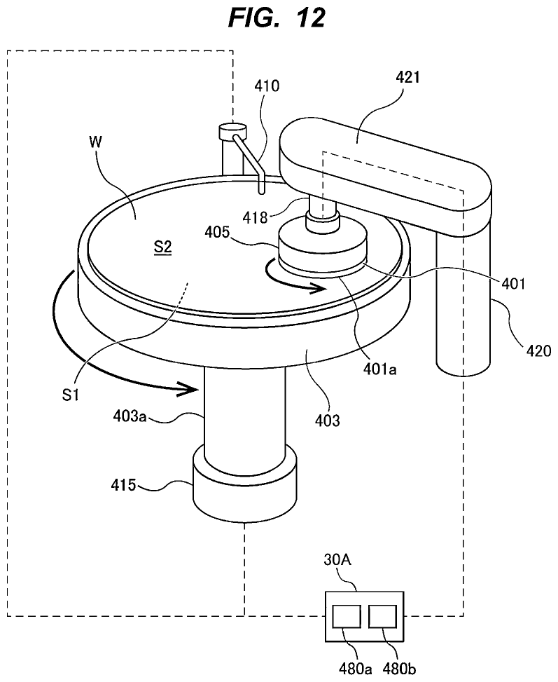

FIG. 12 is a schematic diagram showing an embodiment of the device-surface polishing module. The device-surface polishing module is an apparatus for polishing the device surface of the substrate W. As shown in FIG. 12, the device-surface polishing module includes a buff table 403, a buff head 405, a liquid supply nozzle 410, a table motor 415, a buff-head shaft 418, a support shaft 420, and a buff arm 421.

The buff table 403 is configured to hold the substrate W with the device surface facing upward. In this embodiment, a first surface S1 of the substrate W is a back surface of the substrate W on which no device is formed or device is not to be formed, i.e., a non-device surface. A second surface S2 of the substrate W, which is opposite the first surface S1, is a surface on which devices are formed or devices are to be formed, i.e., a device surface. In this embodiment, the substrate W is horizontally held by the buff table 403 with the second surface S2 facing upward.

The buff table 403 is coupled to a table motor 415 disposed below the buff table 403 via a table shaft 403a. The table motor 415 is configured to rotate the buff table 403 and the substrate W about the table shaft 403a in a direction indicated by an arrow in FIG. 12.

The buff head 405 is configured to hold a buff pad 401 on its lower surface. As shown in FIG. 12, a diameter of the buff pad 401 is smaller than a diameter of the substrate W. The buff pad 401 has a lower surface constituting a polishing surface 401a for polishing the substrate W. The buff head 405 is fixed to a lower end of the buff-head shaft 418, and is rotatable together with the buff-head shaft 418. The buff-head shaft 418 is coupled to the buff arm 421, and is coupled to a not-shown head rotating mechanism disposed in the buff arm 421. The head rotating mechanism is configured to rotate the buff-head shaft 418 and the buff head 405 in a direction indicated by an arrow in FIG. 12.

The buff-head shaft 418 is coupled to a not-shown head vertically moving mechanism disposed in the buff arm 421. The head vertically moving mechanism is configured to move the buff-head shaft 418 and the buff head 405 vertically relative to the buff arm 421. The buff arm 421 is coupled to an upper end of the support shaft 420, and is coupled to a not-shown arm pivoting mechanism disposed in the support shaft 420. The arm pivoting mechanism is configured to cause the buff arm 421 to pivot around the support shaft 420. By the pivoting motion of the buff arm 421, the buff-head shaft 418 and the buff head 405 can be moved between a position above the buff table 403 and a position outside the buff table 403.

The liquid supply nozzle 410 is arranged above the buff table 403. The liquid supply nozzle 410 is configured to supply liquid onto the second surface S2 of the substrate W held on the buff table 403. Examples of the liquid supplied to the second surface S2 of the substrate W include pure water and a chemical liquid (e.g., slurry).

The device-surface polishing module is electrically coupled to the device-surface-polishing control module configured to control operations of each component of the device-surface polishing module. This device-surface-polishing control module corresponds to the control modules 30A or 30B shown in FIG. 11, and in the following description, the device-surface-polishing control module is denoted by a reference symbol 30A. The table motor 415, the head rotating mechanism, the head vertically moving mechanism, the arm pivoting mechanism, and the liquid supply nozzle 410 are electrically coupled to the device-surface-polishing control module 30A. Operations of the table motor 415, the head rotating mechanism, the head vertically moving mechanism, the arm pivoting mechanism, and the liquid supply nozzle 410 are controlled by the device-surface-polishing control module 30A. The device-surface-polishing control module 30A includes a memory 480a and an arithmetic device 480b. The memory 480a and the arithmetic device 480b have the same basic configuration as the memory 180a and the arithmetic device 180b of the notch-polishing control module 30A described above, and duplicated descriptions will be omitted.

Polishing of the second surface S2 of the substrate W is performed as follows. After the substrate W is transported to the device-surface polishing module, the buff table 403 holds the substrate W with the second surface S2 facing upward. The table motor 415 rotates the substrate W held on the buff table 403 about the table shaft 403a. Further, the liquid supply nozzle 410 starts to supply the liquid (e.g., slurry) onto the second surface S2 of the substrate W. In this state, the polishing surface 401a of the buff pad 401 held by the buff head 405 is pressed against the second surface S2 of the substrate W by the head vertically moving mechanism, so that the second surface S2 of the substrate W is polished.

After the second surface S2 of the substrate W is polished according to a predetermined polishing recipe, the device-surface-polishing control module 30A instructs the device-surface polishing module to terminate polishing of the substrate W. Specifically, the device-surface-polishing control module 30A instructs the head vertically moving mechanism to move the buff head 405 away from the substrate W. The device-surface-polishing control module 30A then causes the table motor 415 and the liquid supply nozzle 410 to stop the operations of the table motor 415 and the liquid supply nozzle 410 to terminate polishing of the substrate W.

The specific configuration of the device-surface polishing module is not limited to the above-described embodiment as long as the device-surface polishing module can polish the device surface (i.e., the second surface S2) of the substrate W.

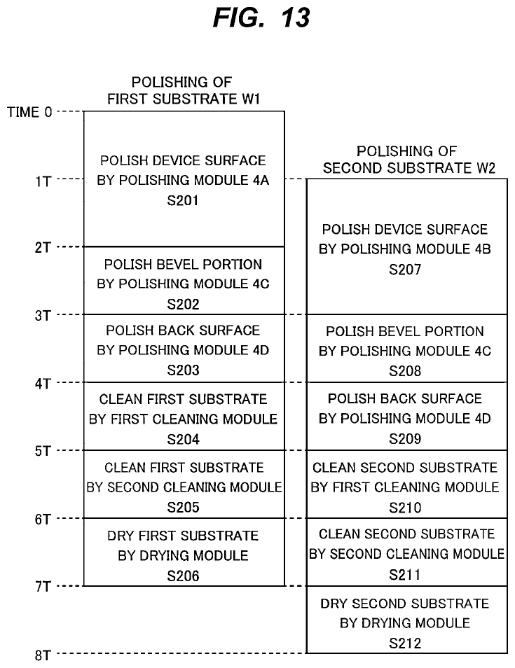

FIG. 13 is a diagram showing an example of a process flow of the substrate polishing apparatus according to the present embodiment. In this embodiment, the device surface (i.e., the second surface S2) of the substrate W is polished by the polishing module 4A or the polishing module 4B which is the device-surface polishing module, the bevel portion B of the substrate W is polished by the polishing module 4C which is the bevel polishing module, and the back surface (i.e., the first surface S1) of the substrate W is polished by the polishing module 4D which is the back-surface polishing module. The polished substrate W is cleaned by the first cleaning module 17, is further cleaned by the second cleaning module 18, and is then dried by the drying module 19.

When polishing time in each polishing module is expressed in time unit T, polishing time for the device surface in the device-surface polishing module is 2T (twice the time unit T), polishing time for the bevel portion B in the bevel polishing module is 1T, and polishing time for the back surface in the back-surface polishing module is 1T. In addition, cleaning time in the first cleaning module 17 and the second cleaning module 18, and drying time in the drying module 19 are each 1T.

FIG. 13 shows a process flow for a first substrate W1 to be processed first and a second substrate W2 to be processed next. Time represents elapsed time from the start of polishing of the first substrate W1.

In step S201, from time 0 to time 2T, a device surface (i.e., a second surface S2) of the first substrate W1 is polished by the polishing module 4A (i.e., the device-surface polishing module).

In step S202, from the time 2T to time 3T, a bevel portion B of the first substrate W1 is polished by the polishing module 4C (i.e., the bevel polishing module).

In step S203, from the time 3T to time 4T, a back surface (i.e., a first surface S1) of the first substrate W1 is polished by the polishing module 4D (i.e., the back-surface polishing module).

In step S204, from the time 4T to time 5T, the polished first substrate W1 is cleaned by the first cleaning module 17.

In step S205, from the time 5T to time 6T, the first substrate W1 that has been cleaned by the first cleaning module 17 is cleaned by the second cleaning module 18.

In step S206, from the time 6T to time 7T, the first substrate W1 that has been cleaned by the second cleaning module 18 is dried by the drying module 19.

In step S207, from time 1T to the time 3T, a device surface (i.e., a second surface S2) of the second substrate W2 is polished by the polishing module 4B (i.e., the device-surface polishing module).

In step S208, from the time 3T to the time 4T, a bevel portion B of the second substrate W2 is polished by the polishing module 4C (i.e., the bevel polishing module).

In step S209, from the time 4T to the time 5T, a back surface (i.e., a first surface S1) of the second substrate W2 is polished by the polishing module 4D (i.e., the back-surface polishing module).

In step S210, from the time 5T to the time 6T, the polished second substrate W2 is cleaned by the first cleaning module 17.

In step S211, from the time 6T to the time 7T, the second substrate W2 that has been cleaned by the first cleaning module 17 is cleaned by the second cleaning module 18.

In step S212, from the time 7T to the time 8T, the second substrate W2 that has been cleaned by the second cleaning module 18 is dried by the drying module 19.

According to this embodiment, since the substrate polishing apparatus includes the device-surface polishing module, the bevel polishing module, and the back-surface polishing module, the substrate polishing apparatus can successively perform polishing of the substrate by the different types of polishing modules. Therefore, it is not necessary to clean and dry the substrate W every time polishing in each polishing module is terminated, and as a result, the overall processing time can be shortened.

The substrate polishing apparatus includes the polishing module 4A and the polishing module 4B, which are device-surface polishing modules that require a longer polishing time than those of other processes. Therefore, the device surfaces (i.e., the second surfaces S2) of the first substrate W1 and the second substrate W2 can be polished in parallel by the polishing module 4A and the polishing module 4B. Thus, in the bevel polishing module that performs the next process, the second substrate W2 can be polished immediately after the first substrate W1 is polished without any idle time. As a result, the overall processing time can be shortened when the plurality of substrates are processed.

The above-described process flow is an example. In one embodiment, the process flow may include polishing of the bevel portion B by the polishing module 4C which is the bevel polishing module, followed by polishing of the back surface (i.e., the first surface S1) by the polishing module 4D which is the back-surface polishing module, and then polishing of the device surface (i.e., the second surface S2) of the substrate W by the polishing module 4A or the polishing module 4B which is the device-surface polishing module.

As shown in FIG. 11, the control modules 30A to 30D of this embodiment include abnormality detecting systems 50A to 50D configured to detect an abnormality that may occur in the corresponding polishing modules 4A to 4D, respectively. Configurations of the abnormality detecting systems 50A to 50D are basically the same as the configurations of the abnormality detecting systems 50A to 50D described with reference to FIG. 8, and duplicated descriptions will be omitted. In one embodiment, the control modules 30A to 30D may not include the abnormality detecting systems 50A to 50D.

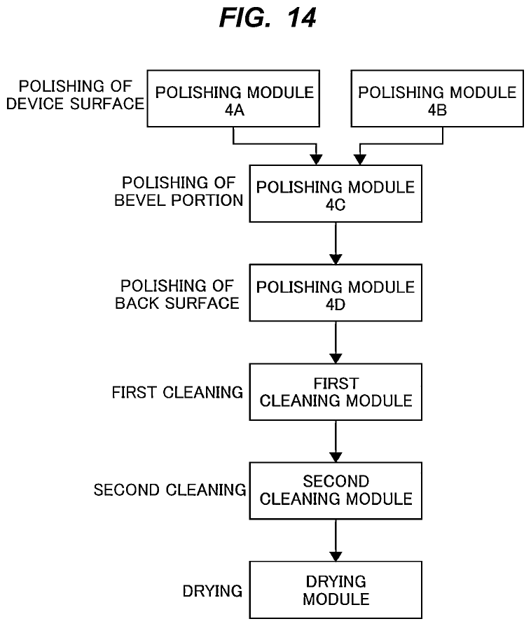

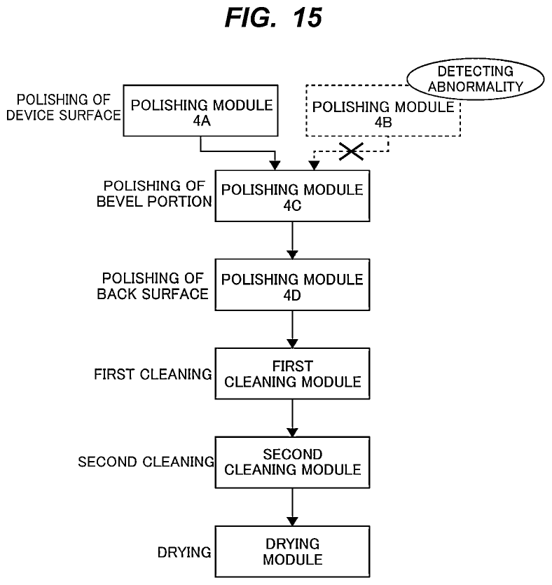

FIG. 14 is a diagram showing a process flow before an abnormality is detected in the substrate polishing apparatus shown in FIG. 11. As in the embodiment described with reference to FIG. 13, polishing of the device surfaces of the plurality of substrates is performed in parallel by the two device-surface polishing modules, which are the polishing module 4A and the polishing module 4B. FIG. 15 is a diagram showing a process flow changed after the abnormality in the polishing module 4B is detected in the substrate polishing apparatus shown in FIG. 11. When the abnormality in the polishing module 4B is detected by the abnormality detecting system 50B, the control module 30B transmits an abnormality detection signal to the management controller 20. The management controller 20 creates a process flow which is performed without using the polishing module 4B based on the abnormality detection signal, and changes a process flow from the process flow shown in FIG. 14 which is performed using both the polishing modules 4A and 4B to the process flow shown in FIG. 15 which is performed using the polishing module 4A and is performed without using the polishing module 4B.

In this present embodiment, the polishing module 4B in which the abnormality has been detected is one of the plurality of device-surface polishing modules. Therefore, when the abnormality has occurred in the polishing module 4B, the substrate polishing apparatus can continue the processing of the substrate without stopping the operations of the entire substrate polishing apparatus by changing the process flow so as to polish the device surface using only the polishing module 4A.

The substrate polishing apparatus of this embodiment is provided with the two device-surface polishing modules, while in another embodiment, the substrate polishing apparatus may include three or more device-surface polishing modules. When the abnormality detecting system detects an abnormality in at least one of the three or more device-surface polishing modules, the management controller 20 may change a process flow so as to not use the at least one device-surface polishing module in which the abnormality has been detected. In one embodiment, the substrate polishing apparatus may include a plurality of bevel polishing modules or a plurality of back-surface polishing modules. When the abnormality detecting system detects an abnormality in a bevel polishing module of the plurality of bevel polishing modules or a back-surface polishing module of the plurality of back-surface polishing modules, the management controller 20 may change a process flow so as to not use the bevel polishing module or the back-surface polishing module in which the abnormality has been detected.

In the embodiment described with reference to FIGS. 11 to 15, the substrate polishing apparatus includes three types of polishing modules, which are the device-surface polishing module, the bevel polishing module, and the back-surface polishing module, while the configuration of the substrate polishing apparatus is not limited to this embodiment as long as the substrate polishing apparatus includes at least three of four types of polishing modules which are the device-surface polishing module, the notch polishing module, the bevel polishing module, and the back-surface polishing module. For example, the substrate polishing apparatus may include three types of polishing modules, which are the device-surface polishing module, the notch polishing module, and the bevel polishing module. In another example, the substrate polishing apparatus may include four types of polishing modules, which are the device-surface polishing module, the notch polishing module, the bevel polishing module, and the back-surface polishing module.

In addition, in this embodiment, the substrate polishing apparatus includes four polishing modules 4A to 4D, while the configuration of the substrate polishing apparatus is not limited to this embodiment as long as the substrate polishing apparatus includes at least three of the four types of polishing modules which are the device-surface polishing module, the notch polishing module, the bevel polishing module, and the back-surface polishing module. For example, the substrate polishing apparatus may include six polishing modules including four types of polishing modules, which are two device-surface polishing modules, two notch polishing modules, one bevel polishing module, and one back-surface polishing module.

In one embodiment, the substrate polishing apparatus may include at least two types selected from the device-surface polishing module, the notch polishing module, the bevel polishing module, and the back-surface polishing module, and each of the at least two types selected includes two or more polishing modules of the same configuration. When an abnormality is detected in one of the two or more polishing modules of the same configuration, the management controller 20 may change a process flow so as to not use the polishing module in which the abnormality has been detected. For example, the substrate polishing apparatus may include six polishing modules including four types of polishing modules, which are two device-surface polishing modules, two notch polishing modules, one bevel polishing module, and one back-surface polishing module. When an abnormality is detected in the device-surface polishing module or the notch polishing module, the management controller 20 may change a process flow so as to not use the device-surface polishing module or the notch polishing module in which the abnormality has been detected.

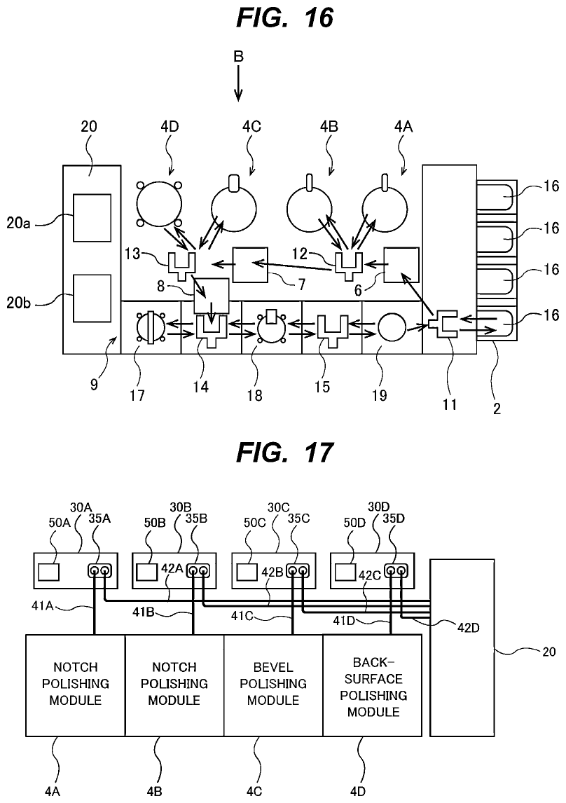

FIG. 16 is a plan view showing still another embodiment of the substrate polishing apparatus, and FIG. 17 is a side view of the substrate polishing apparatus shown in FIG. 16 as viewed from a direction indicated by an arrow B. Configurations and operations of this embodiment, which will not be particularly described, are the same as those of the embodiment described with reference to FIG. 1 and FIG. 2, and duplicated descriptions will be omitted. The substrate polishing apparatus of this embodiment does not include the above-described housing 1. At least a part of each of the four polishing modules 4A to 4D is exposed to an outside of the substrate polishing apparatus. The four polishing modules 4A to 4D are aligned in a straight line when viewed from above the substrate polishing apparatus. The polishing module 4A is adjacent to the polishing module 4B, the polishing module 4B is adjacent to the polishing modules 4A and 4C, the polishing module 4C is adjacent to the polishing modules 4B and 4D, and the polishing module 4D is adjacent to the polishing module 4C.

The polishing modules 4A to 4D of this embodiment include three types of polishing modules which are the notch polishing module configured to polish the notch of the substrate, the bevel polishing module configured to polish the bevel portion of the substrate, and the back-surface polishing module configured to polish the back surface of the substrate. The three types of polishing modules included in the polishing modules 4A to 4D are polishing modules that polish different regions of the substrate. More specifically, the polishing module 4A and the polishing module4B are the notch polishing modules, the polishing module 4C is the bevel polishing module, and the polishing module 4D is the back-surface polishing module.

In this embodiment, the substrate polishing apparatus includes four polishing modules 4A to 4D, while the configuration of the substrate polishing apparatus is not limited to this embodiment as long as the substrate polishing apparatus includes at least three of the four types of polishing modules which are the notch polishing module, the bevel polishing module, the back-surface polishing module, and the device-surface polishing module configured to polish the different regions of the substrate, respectively. For example, the substrate polishing apparatus may include six polishing modules including four types of polishing modules, which are two notch polishing modules, two device-surface polishing modules, one bevel polishing module, and one back-surface polishing module.

The polishing modules 4A to 4D have the same size. Therefore, the arrangements of the notch polishing module, the bevel polishing module, and the back-surface polishing module constituting the polishing modules 4A to 4D can be changed. For example, each of the polishing module 4A and the polishing module 4B may be the bevel polishing module, the polishing module 4C may be the back-surface polishing module, and the polishing module 4D may be the notch polishing module.

In this embodiment, the notch of the substrate is polished by at least one of the polishing modules 4A and 4B. The bevel portion of the substrate is then polished by the polishing module 4C, and the back surface of the substrate is polished by the polishing module 4D. This process flow, i.e., each of the type of polishing module to be used and the operation order of the polishing modules, is one example, and the process flow is not limited to this embodiment.

The substrate polishing apparatus includes four control modules 30A to 30D configured to control the operations of the polishing modules 4A to 4D, respectively. The four control modules 30A to 30D are aligned in a straight line when viewed from above the substrate polishing apparatus. The control modules 30A to 30D are disposed above the polishing modules 4A to 4D, respectively. Specifically, the control module 30A is disposed above the polishing module 4A, the control module 30B is disposed above the polishing module 4B, the control module 30C is disposed above the polishing module 4C, and the control module 30D is disposed above the polishing module 4D.

In this embodiment, each of the control module 30A and the control module 30B are a notch-polishing control module configured to control the operations of the notch polishing module, the control module 30C is a bevel-polishing control module configured to control the operation of the bevel polishing module, and the control module 30D is a back-surface-polishing control module configured to control the operation of the back-surface polishing module.

The control modules 30A to 30D include wire connectors 35A to 35D, respectively. Specifically, the control module 30A includes the wire connector 35A which can be electrically coupled to the management controller 20 and the polishing module 4A. The control module 30B includes the wire connector 35B which can be electrically coupled to the management controller 20 and the polishing module 4B. The control module 30C includes the wire connector 35C which can be electrically coupled to the management controller 20 and the polishing module 4C. The control module 30D includes the wire connector 35D which can be electrically coupled to the management controller 20 and the polishing module 4D.

In the embodiment shown in FIGS. 16 and 17, when the arrangements of the polishing modules 4A to 4D are changed, the arrangements of the control modules 30A to 30D can also easily be changed together with the corresponding polishing modules 4A to 4D.

As shown in FIG. 17, the control modules 30A to 30D of this embodiment include abnormality detecting systems 50A to 50D configured to detect an abnormality that may occur in the corresponding polishing modules 4A to 4D, respectively. Configurations and operations of the abnormality detecting systems 50A to 50D are basically the same as the configurations and the operations of the abnormality detecting systems 50A to 50D described with reference to FIGS. 8 to 10, and duplicated descriptions will be omitted. In one embodiment, the control modules 30A to 30D may not include the abnormality detecting systems 50A to 50D.

In the substrate polishing apparatus shown in FIGS. 16 and 17, when an abnormality occurs in one of the polishing modules 4A and 4B, the substrate polishing apparatus can continue the processing of the substrate without stopping the operations of the entire substrate polishing apparatus by changing the process flow so as to use only the other of the polishing modules 4A and 4B in which the abnormality does not occur.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate polishing apparatus for polishing a notch of a substrate, a bevel portion of the substrate, a device surface of the substrate, and a back surface of the substrate.

### REFERENCE SIGNS LIST

1 housing
2 load port
4A, 4B, 4C, 4D polishing module
6 first temporary station
7 second temporary station
8 third temporary station
9 cleaning-drying section
11 first transfer robot
12 second transfer robot
13 third transfer robot
14 fourth transfer robot
15 fifth transfer robot
16 substrate cassette
17 first cleaning module
18 second cleaning module
19 drying module
20 management controller
20a memory
20b arithmetic device
30A, 30B, 30C, 30D control module
35A wire connector
35B wire connector
35C wire connector
35D wire connector
41A, 41B, 41C, 41D polishing-module wire
42A, 42B, 42C, 42D body wire
50A, 50B, 50C, 50D abnormality detecting system
102 polishing tape
103 polishing head
105 substrate holder
107 holding stage
108 first shaft
109 holding-stage driving mechanism
110 substrate swinging mechanism
112 swing arm
113 second shaft
114 swing mechanism
120 polishing-tape feeding mechanism
121 tape feeding reel
122 tape take-up reel
124, 125, 126, 127 guide roller
128 reel base
130 liquid supply nozzle
140 notch detector
150 polishing-head moving mechanism
152 movable plate
154 guide rail
155 air cylinder
156 coupling shaft
160 base plate
170 tilting mechanism
172 crank arm
173 arm rotating device
202 polishing tape
203 polishing head
205 substrate holder
207 holding stage
208 shaft
209 holding-stage driving mechanism
220 polishing-tape feeding mechanism
221 tape feeding reel
222 tape take-up reel
224, 225, 226, 227 guide roller
228 reel base
231 lower supply nozzle
232 upper supply nozzle
242 pressing member
245 air cylinder (actuator)
302 polishing tape
303 polishing head
305 substrate holder
308 roller
320 polishing-tape feeding mechanism
321 tape feeding reel
322 tape take-up reel
324, 325, 326, 327 guide roller
331 rinsing-liquid supply nozzle
332 protective-liquid supply nozzle
340 movable plate
342 pressing member
343 support member
345 air cylinder (actuator)
350 polishing-head moving mechanism
352 ball screw mechanism
355 linear guide
360 base plate
401 buff pad
403 buff table
403a table shaft
405 buff head
410 liquid supply nozzle
415 table motor
418 buff-head shaft
420 support shaft
421 buff arm

1. A substrate polishing apparatus comprising:
a first polishing module;
a second polishing module; and
a third polishing module;
wherein the first polishing module, the second polishing module, and the third polishing module are configured to polish different regions of a substrate.

2. The substrate polishing apparatus according to claim 1, wherein the first polishing module, the second polishing module, and the third polishing module are aligned in a straight line when viewed from above the substrate polishing apparatus.

3. The substrate polishing apparatus according to claim 1, wherein
the first polishing module is one of a notch polishing module configured to polish a notch of the substrate, a bevel polishing module configured to polish a bevel portion of the substrate, and a back-surface polishing module configured to polish a back surface of the substrate,
the second polishing module is other one of the notch polishing module, the bevel polishing module, and the back-surface polishing module, and
the third polishing module is a remaining one of the notch polishing module, the bevel polishing module, and the back-surface polishing module.

4. The substrate polishing apparatus according to claim 1, wherein
the first polishing module is one of a device-surface polishing module configured to polish a device surface of the substrate, a bevel polishing module configured to polish a bevel portion of the substrate, and a back-surface polishing module configured to polish a back surface of the substrate,
the second polishing module is other one of the device-surface polishing module, the bevel polishing module, and the back-surface polishing module, and
the third polishing module is a remaining one of the device-surface polishing module, the bevel polishing module, and the back-surface polishing module.

5. The substrate polishing apparatus according to claim 1, further comprising:
a housing,
wherein the first polishing module, the second polishing module, and the third polishing module are arranged in the housing.

6. The substrate polishing apparatus according to claim 5, further comprising:
a first control module configured to control an operation of the first polishing module;
a second control module configured to control an operation of the second polishing module; and
a third control module configured to control an operation of the third polishing module,
wherein the first to third polishing modules and the first to third control modules are detachably arranged in the housing.

7. The substrate polishing apparatus according to claim 6, wherein the first to third polishing modules have the same size, and the first to third control modules have the same size.

8. The substrate polishing apparatus according to claim 6, further comprising:
a management controller configured to control operations of the first to third polishing modules and the first to third control modules,
wherein the first control module includes a first wire connector which can be electrically coupled to the management controller and the first polishing module,
the second control module includes a second wire connector which can be electrically coupled to the management controller and the second polishing module, and
the third control module includes a third wire connector which can be electrically coupled to the management controller and the third polishing module.

9. The substrate polishing apparatus according to claim 6, further comprising:
a fourth polishing module arranged in the housing;
a fourth control module detachably arranged in the housing, the fourth control module being configured to control an operation of the fourth polishing module;
an abnormality detecting system configured to detect an abnormality that occurs in any one of the first to fourth polishing modules; and
a management controller configured to control operations of the first to fourth polishing modules and the first to fourth control modules,
wherein each of the first polishing module and the fourth polishing module is one of a notch polishing module configured to polish a notch of the substrate, a bevel polishing module configured to polish a bevel portion of the substrate, a back-surface polishing module configured to polish a back surface of the substrate, and a device-surface polishing module configured to polish a device surface of the substrate, and
the management controller is configured to create a process flow which is performed using the fourth polishing module and without using the first polishing module when the abnormality detecting system detects an abnormality in the first polishing module.

10. The substrate polishing apparatus according to claim 1, further comprising:
a first control module configured to control an operation of the first polishing module;
a second control module configured to control an operation of the second polishing module;
a third control module configured to control an operation of the third polishing module; and
a management controller configured to control operations of the first to third polishing modules and the first to third control modules,
wherein the first control module includes a first wire connector which can be electrically coupled to the management controller and the first polishing module,
the second control module includes a second wire connector which can be electrically coupled to the management controller and the second polishing module, and
the third control module includes a third wire connector which can be electrically coupled to the management controller and the third polishing module.

11. The substrate polishing apparatus according to claim 10, further comprising:
a fourth polishing module;
a fourth control module configured to control an operation of the fourth polishing module; and
an abnormality detecting system configured to detect an abnormality that occurs in any one of the first to fourth polishing modules,
wherein each of the first polishing module and the fourth polishing module is one of a notch polishing module configured to polish a notch of the substrate, a bevel polishing module configured to polish a bevel portion of the substrate, a back-surface polishing module configured to polish a back surface of the substrate, and a device-surface polishing module configured to polish a device surface of the substrate, and
the management controller is configured to control operations of the first to fourth polishing modules and the first to fourth control modules, the management controller being configured to create a process flow which is performed using the fourth polishing module and without using the first polishing module when the abnormality detecting system detects an abnormality in the first polishing module.
